(19) United States
(12) Patent Application Publication
(10) Pub. No.: US 2026/0354264 A1
(43) Pub. Date: Nov. 5, 2026

(54) SEMICONDUCTOR DEVICE HAVING AN INTEGRATED CAPACITOR

(71) Applicant: Sandisk Technologies, Inc., Milpitas, CA (US)

(72) Inventors: Subodh Dubey, Bangalore (IN); Ramkumar B, Bangalore (IN); Palanikumar Sivasubramanian, Bangalore (IN); Ankit Kumar, Bangalore (IN)

(73) Assignee: Sandisk Technologies, Inc., Milpitas, CA (US)

(21) Appl. No.: 19/198,847

(22) Filed: May 5, 2025

(51) Int. Cl. H10W 90/00; H10D 1/68; H10W 44/00; H10W 70/60; H10W 72/00

(52) U.S. Cl. CPC H10W 90/00; H10D 1/692; H10W 44/601; H10W 70/60; H10W 70/611; H10W 72/884; H10W 90/732; H10W 90/738; H10W 90/752; H10W 90/754

(57) ABSTRACT

A DAF-C semiconductor device includes an integrated capacitor. In examples, the DAF-C semiconductor device includes a semiconductor die mounted on a metal enclosed film (MEF) comprised of a first metal layer sandwiched between a die attach film and wire embedded film. The die and MEF layer are mounted on a substrate having a second metal layer to form the DAF-C semiconductor device. The first and second metal layers of the semiconductor device together form the plates of a capacitor integrated into the semiconductor device.

### BACKGROUND

The strong growth in demand for portable consumer electronics is driving the need for high-capacity storage devices. Non-volatile semiconductor memory devices, such as flash memory storage cards, are widely used to meet the ever-growing demands on digital information storage and exchange. The non-volatile memory products portability, versatility and customized design, along with their high reliability and ultra-high capacity, have made such memory devices ideal for use in a wide variety of electronic devices, including for example digital cameras, digital music players, video game consoles, PDAs, cellular telephones and solid state drives (SSDs).

While many varied packaging configurations are known, flash memory semiconductor packages may in general be assembled as system-in-a-package (SIP), where a controller die and a number of memory dies such as 3D BiCS (Bit Cost Scaling) and V-NAND are mounted and interconnected to an upper surface of substrate such as a printed circuit board. Electrical connections are formed between the dies and the substrate and the package may then be encapsulated in mold compound.

Current high-speed memory devices use PCIe (Peripheral Component Interconnect Express) or other high-speed serial interface standards to communicate signals. In high-speed signal communications through a PCB, it is important to minimize noise and insertion losses as electrical signals travel through the signal pathway formed by traces and vias. To help mitigate signal degradation and maintain signal integrity, high-speed memory devices typically include decoupling capacitors. These capacitors provide local energy storage and help to stabilize voltage levels by filtering out high-frequency noise and supplying transient current demands. This reduces power supply fluctuations and ensures clean and reliable signal transmission, which is critical for the proper functioning of the device.

While necessary for proper operation of high-speed interfaces, surface mounting of conventional capacitors on the substrate has certain drawbacks. Firstly, most conventional capacitors add to the height of a semiconductor package, where minimizing the height is critical. Further, proper picking, placing and surface mounting of conventional capacitors is challenging using existing pick and place robots. Moreover, conventional capacitors are surface mounted at two points on a substrate, and often one side of the surface mounting fails, resulting in a tombstoning effect Other common defects from surface mount capacitors include component misalignment, damage and placement inaccuracies.

### DESCRIPTION OF THE DRAWINGS

FIG. 1 is a flowchart for forming memory die and metal embedded film according to embodiments of the present technology.

FIG. 2 is a top view of a semiconductor wafer, and a semiconductor die therefrom, according to embodiments of the present technology.

FIG. 3 is a top view of a metal embedded film according to embodiments of the present technology.

FIG. 4 is a cross-sectional edge view of the metal embedded film through line 4-4 of FIG. 3.

FIG. 5 is a cross-sectional edge view of a complete semiconductor die including an attached metal embedded film according to embodiments of the present technology.

FIG. 6 is a flowchart for forming a DAF-C semiconductor device according to embodiments of the present technology.

FIG. 7 is a cross-sectional edge view of a substrate according to embodiments of the present technology.

FIG. 8 is a cross-sectional edge view of a DAF-C semiconductor device during assembly as per the flowchart of FIG. 6.

FIG. 9 is a top view of the DAF-C semiconductor device of FIG. 8 during assembly.

FIG. 10 is a cross-sectional edge view of a DAF-C semiconductor device during assembly as per the flowchart of FIG. 6.

FIG. 11 is a cross-sectional edge view of a DAF-C semiconductor device during assembly per the flowchart of FIG. 6.

FIG. 12 is a top view of the DAF-C semiconductor device of FIG. 11 during assembly.

FIG. 13 is a cross-sectional edge view of a completed DAF-C semiconductor device according to embodiments of the present technology.

FIG. 14 is a cross-sectional edge view of the DAF-C capacitor of the semiconductor device according to embodiments of the present technology.

FIG. 15 is a top view of the portion of the DAF-C capacitor formed in the substrate according to embodiments of the present technology.

FIG. 16 is a cross-sectional edge view of the DAF-C capacitor of the semiconductor device according to alternative embodiments of the present technology.

FIG. 17 is a top view of the portion of the DAF-C capacitor formed in the substrate in FIG. 16 according to embodiments of the present technology.

FIG. 18 is a cross-sectional edge view of the DAF-C capacitor of the semiconductor device according to alternative embodiments of the present technology.

FIG. 19 is a top view of the portion of the DAF-C capacitor formed in the substrate in FIG. 18 according to embodiments of the present technology.

FIG. 20 is a cross-sectional edge view of the DAF-C capacitor of the semiconductor device according to alternative embodiments of the present technology.

FIG. 21 is a top view of the portion of the DAF-C capacitor formed in the substrate in FIG. 20 according to embodiments of the present technology.

FIG. 22 is a cross-sectional edge view of the DAF-C capacitor of the semiconductor device according to alternative embodiments of the present technology.

FIG. 23 is a top view of the portion of the DAF-C capacitor formed in the substrate in FIG. 22 according to embodiments of the present technology.

FIG. 24 is a cross-sectional edge view of a DAF-C semiconductor device according to embodiments of the present technology.

### DETAILED DESCRIPTION

The present technology will now be described with reference to the figures, which in embodiments, relate to a DAF-C semiconductor device having an integrated capacitor. In embodiments, the DAF-C semiconductor device includes a semiconductor die mounted on a metal enclosed film (MEF) comprised of a first metal layer sandwiched between a die attach film and wire embedded film. The die and MEF layer are mounted on a substrate having a second metal layer to form the DAF-C semiconductor device. The first and second metal layers of the semiconductor device together form the plates of a capacitor integrated into the semiconductor device. The parameters of the metal layers, such as their size, thickness and spacing, may be controlled to provide different amounts of capacitance which may be customized as needed in different examples of the semiconductor device.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal,” and forms thereof, as may be used herein are by way of example and illustrative purposes only, and are not meant to limit the description of the technology in as much as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is ±0.15 mm, or alternatively, ±2.5% of a given dimension.

For purposes of this disclosure, a physical or electrical connection may be a direct connection or an indirect connection (e.g., via one or more other parts). In some cases, when a first element is referred to as being connected, affixed, mounted or coupled to a second element (either physically or electrically), the first and second elements may be directly connected, affixed, mounted or coupled to each other or indirectly connected, affixed, mounted or coupled to each other (either physically or electrically). When a first element is referred to as being directly connected, affixed, mounted or coupled to a second element, then there are no intervening elements between the first and second elements (other than possibly an adhesive or melted metal used to connect, affix, mount or couple the first and second elements).

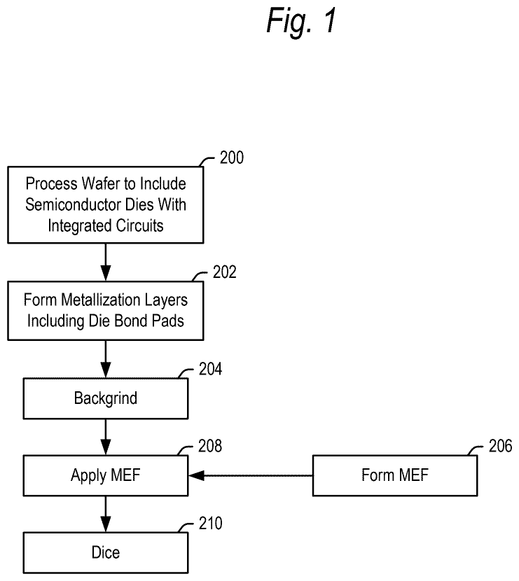

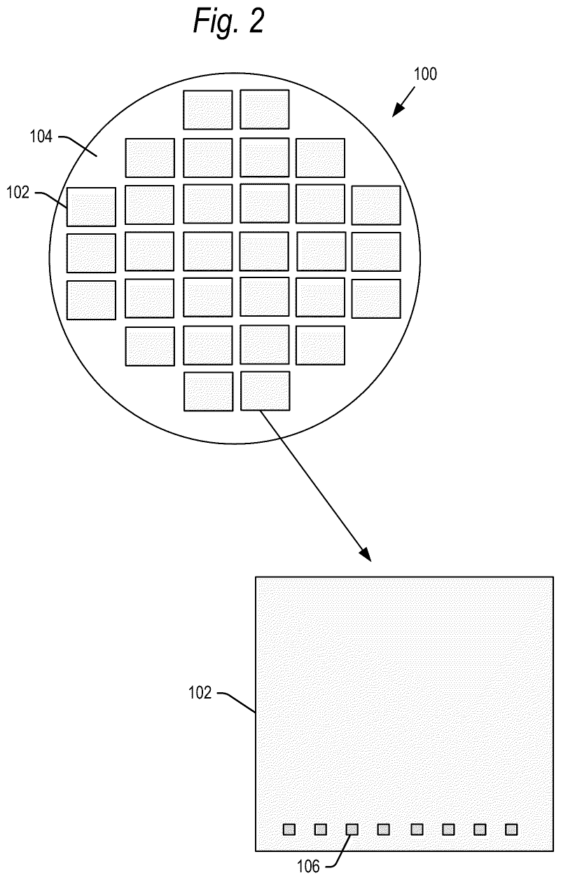

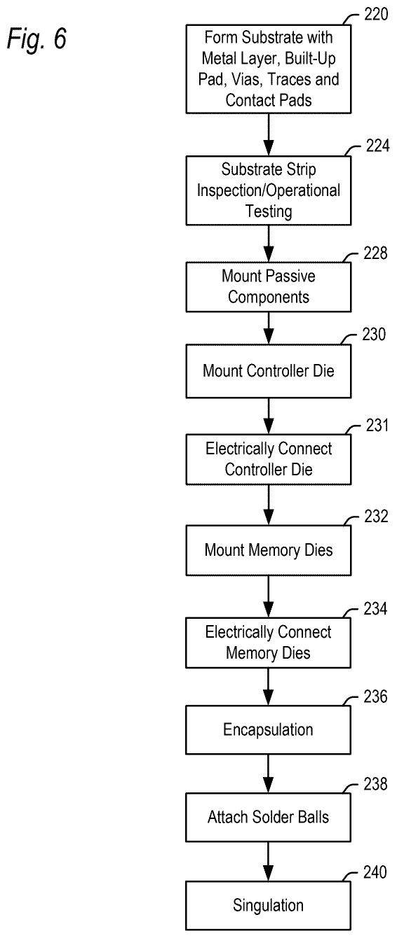

Embodiments of the present technology will now be explained with reference to the flowcharts of FIGS. 1 and 6, and the views of FIGS. 2-5 and 7-24. In step 200, a semiconductor wafer 100 may be processed into a number of semiconductor dies 102 as shown in FIG. 2. Although not critical to the present technology, the semiconductor wafer 100 may start as an ingot of wafer material which may be monocrystalline silicon grown according to either a Czochralski (CZ) or floating zone (FZ) process. The wafer 100 may be formed of other materials and by other processes in further embodiments. The first major surface 104 of wafer 100 may undergo various processing steps to divide the wafer 100 into the respective semiconductor dies 102, and to form integrated circuits of the respective semiconductor dies 102 on and/or in the first major surface 104. In step 202, metallization layers may be formed in the wafer 100, including depositing metal contacts including die bond pads 106 exposed on the first major surface 104. The metallization step 202 may further include depositing metal interconnect layers and vias within the wafer. These metal interconnect layers and vias may be provided for transferring signals between the integrated circuits and the contact pads 106, and to provide structural support to the integrated circuits as is known. After formation of the integrated circuits and bond pads, the wafer 100 may be flipped over and a backgrind process may be performed on the inactive surface to thin the wafer (step 204).

The semiconductor dies 102 may for example be memory dies such as 2D NAND flash memory or 3D BiCS (Bit Cost Scaling), V-NAND or other 3D flash memory. However, dies 102 may be other types of dies, including for example RAM such as an SDRAM, DDR SDRAM, LPDDR and GDDR. The number of semiconductor dies 102 shown on wafer 100 in FIG. 2 is for illustrative purposes, and wafer 100 may include more semiconductor dies 102 than are shown in further embodiments. Similarly, the number and pattern of bond pads 106 on the semiconductor dies 102 in FIG. 2 is shown for illustrative purposes, and the dies 102 may include bond pads 106 in different patterns and in different numbers than are shown in further embodiments.

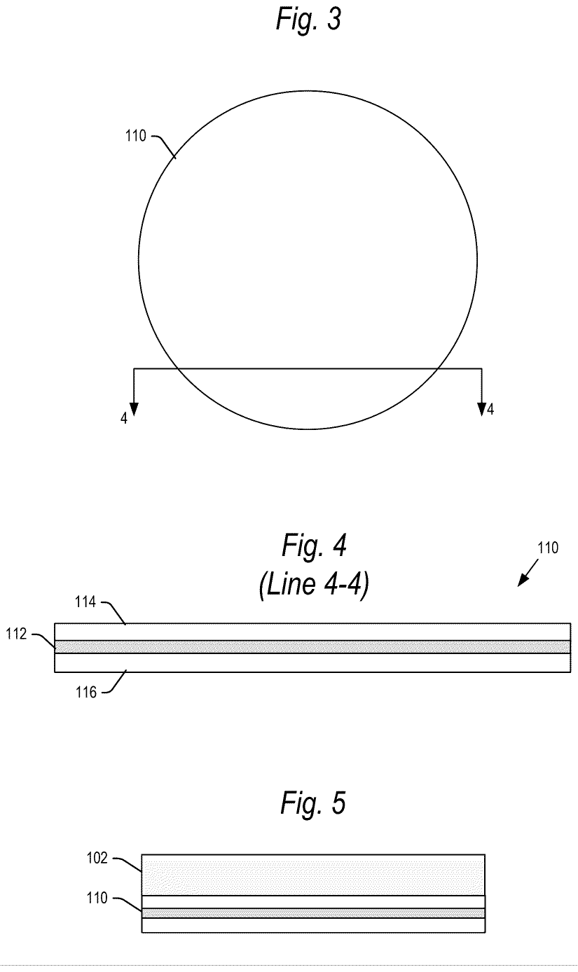

Before, during or after formation of semiconductor dies 102 in wafer 100, a metal embedded film (MEF) 110 may be formed in step 206 and as shown in FIGS. 3 and 4. The MEF 110 may be formed of a metal layer 112 sandwiched between a die attach film (DAF) 114 and a wire embedded film (WEF) 116. The DAF 114 may be a polymer-based film (e.g., epoxy resin or polyimide), optionally filled with thermally conductive but electrically insulating particles such as silica (SiO₂). The DAF 114 adheres the MEF 110 to the wafer 100 and dies 102, and forms a dielectric barrier between dies 102 and the metal layer 112.

The metal layer 112, also referred to herein as metal plate 112, serves as the first (upper) plate electrode of the integrated DAF-C capacitor. The second (bottom) layer is formed in a substrate on which the MEF 110 is mounted as explained below. The layer 112 may serve as a reference plane (e.g., power or ground), and may be formed of high-conductivity metal such as copper (Cu), aluminum (Al), or tungsten (W). In embodiments, layer 112 may include barrier or adhesion layers (e.g., titanium or tantalum) to enhance mechanical stability and prevent diffusion or delamination, though these may be omitted from layer 112 in further embodiments.

The WEF 116 is mounted below the metal layer 11. The WEF 116 may be formed of various soft, compliant and electrically insulating materials such as polyimide or epoxy resin films. As explained below, a built-up electrical conductor on the substrate may embed within the WEF 116 when the die 102 and MEF 110 are mounted on a substrate. As explained below, the WEF 116 is the layer responsible for bonding the die 102 and MEF 110 to the substrate. The WEF 116 may be pre-treated or layered to improve its ability to bond to the substrate.

In step 208, the MEF 110 is adhered to the inactive surface of the wafer 100. In the embodiment shown the MEF is formed into a circular shape with a size similar to that of the wafer. However, the MEF 110 may be deployed in a sheet from a roll in further embodiments. Once the MEF 110 is adhered to the inactive surface of the wafer 100, the wafer 100 may be flipped over and diced in step 210. The dies 102 and MEF 110 may be diced from the wafer 100 by various methods including saw blade and laser. The wafer 100 may be diced in step 210 to form individual semiconductor dies 102 with an affixed MEF 110 as shown in cross-sectional edge view of FIG. 5.

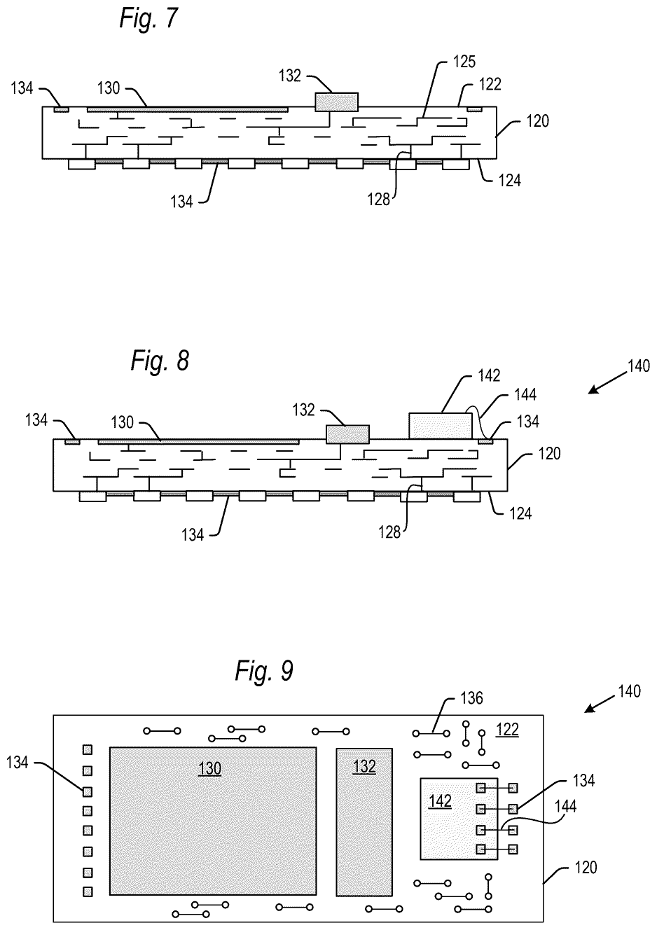

Once formed, the die 102 with MEF 110 may be mounted on a substrate as will now be described with reference to the flowchart of FIG. 6 and the views of FIGS. 7-24. The substrate 120 may be formed in step 220 as shown in the cross-sectional edge view of FIG. 7. The substrate 120 may be formed to include conductive layers on at least a first (e.g., top) major surface 122 and a second (e.g., bottom) major surface 124. The substrate 120 may further include additional internal conductive layers 125. Each of the conductive layers, 122, 124, 125 may be separated by dielectric cores. The conductive layers 122, 124, 125 for example be formed of high-conductivity metal such as copper (Cu), though other materials such as aluminum (Al) or tungsten (W) are possible. Electrically conductive vias 128 may be formed through the dielectric core to electrically interconnect the various conductive layers.

In accordance with aspects of the present technology, the conductive layers may be etched in a photolithographic process to define a plate, or metal layer, 130 and ground pad 132 on and/or in the first major surface 122 as shown for example in the cross-sectional edge view of FIGS. 7 and 8 and the top view of FIG. 9. The size of metal layer 130 may be the same as the size of the conductive layer 112 in the MEF 110. The ground pad 132 may be built-up by adding additional metal layers during the metallization steps to extend a surface of the ground pad 132 above a surface of the substrate 120. The conductive surfaces 122, 124 may further be etched to include contact pads 134 and electrical traces 136 as seen for example in FIGS. 7 and 9.

The pattern of vias 128, contact pads 134 and electrical traces 136 are used to route electrical signals along and between the first and second major surfaces 122, 124. The patterns of vias 128, contact pads 134 and traces 136 shown in the figures is for illustrative purposes only and may vary in further embodiments. The figures show a single substrate 120, but it is understood that the semiconductor package of the present technology may be assembled from a panel of substrates to achieve economies of scale.

The completed substrate 120 may be inspected and operationally tested in step 224. These inspections may for example include an automatic optical inspection (AOI), an automated visual inspection (AVI) and/or a final visual inspection (FVI) to check for defects, contamination, scratches and discoloration. One or more of these steps may be omitted or performed in a different order in further embodiments. Assuming the substrate 120 passes inspection, passive components (other than capacitors) may next be affixed to the top surface 122 of the substrate 120 in a step 228. The one or more passive components may include for example one or more resistors and/or inductors, though other components are contemplated.

In step 230, a controller die 142 may be mounted on the first major surface 122 to form a (partial) semiconductor device 140 as shown for example in the cross-sectional edge view of FIG. 8 and top view of FIG. 9. The controller die 142 may for example be an ASIC for controlling transfer of signals and data to and from the memory dies 102 (affixed to the substrate 120 as explained below). Controller die 142 may additionally or alternatively be a specialized processor such as for example an artificial intelligence (AI) chip or graphics processing unit (GPU).

In step 231, the controller die 142 may be electrically interconnected to the contact pads 134 of the substrate 120 as shown in FIGS. 8 and 9. In one example, the step 231 may involve forming bond wires 144 between die bond pads on the controller die and the contact pads 134 on substrate 120. The bond wires 144 may be formed by a ball-bonding technique, but other wire bonding techniques are possible. The controller die 142 may be electrically interconnected to the substrate 120 by other methods in further embodiments, including by through-silicon vias (TSVs) and flip-chip technologies.

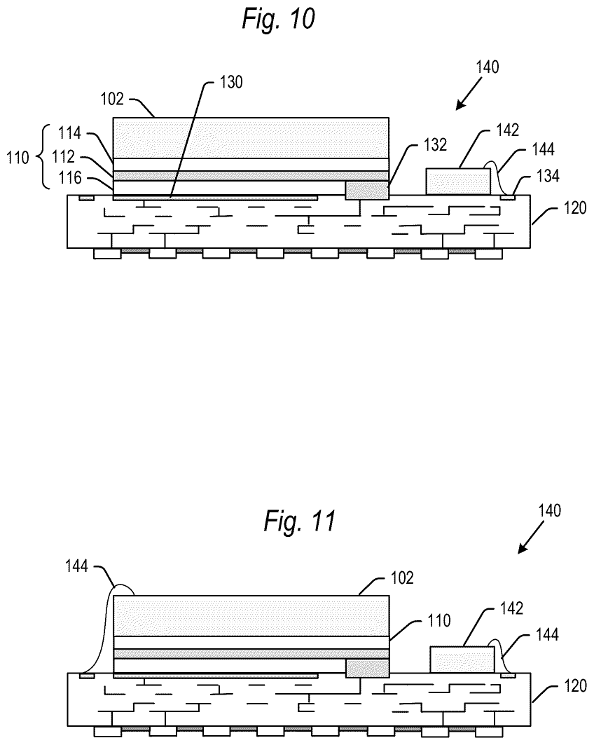

In step 232, a semiconductor 102 with MEF 110 may be mounted on the first major surface 122 of the substrate 120 to form the semiconductor device 140, also referred to herein as a DAF-C semiconductor device 140. As shown in the cross-sectional edge view of FIG. 10, the die 102 may be mounted by adhering the WEF 116 of MEF 110 directly on top of the metal layer 130 on the first major surface 122 of substrate 120. Moreover, upon mounting the die 102 and MEF 110 on substrate 120, the ground pad 132 embeds within the WEF 116 to lie in direct contact with the metal layer 112, thus electrically coupling the layer 112 to the substrate 120.

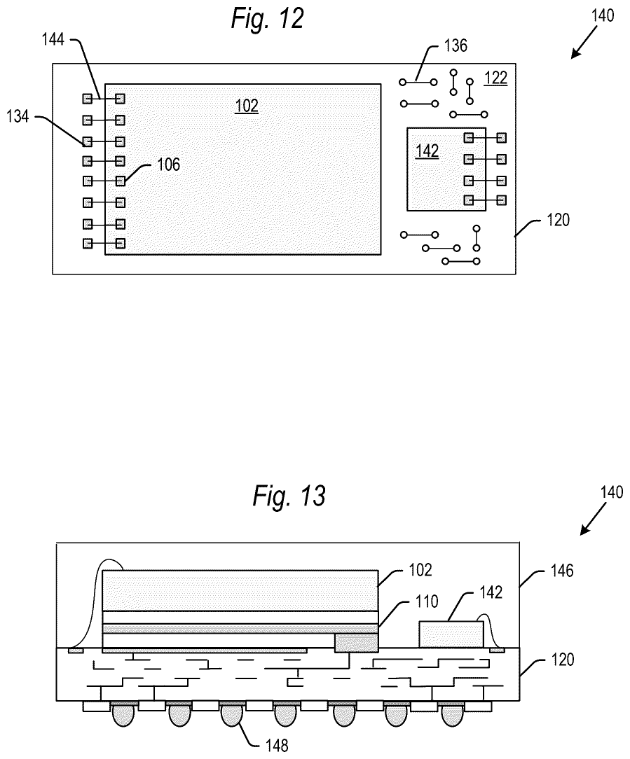

In step 234, the semiconductor die 102 may be electrically interconnected to the contact pads 134 of the substrate 120 as shown in FIGS. 11 and 12. In one example, the step 234 may involve forming bond wires 144 between die bond pads 106 on the semiconductor die 102 and the contact pads 134 on substrate 120. The bond wires 144 may be formed by a ball-bonding technique, but other wire bonding techniques are possible. The semiconductor die 102 may be electrically interconnected to the substrate 120 by other methods in further embodiments. FIGS. 11 and 12 show the controller die 142 mounted alongside of the semiconductor die 102. However, in further embodiments, the controller die may be mounted to the substrate 120 first. And thereafter, the controller die 142 may be mounted on top of die 102 as opposed to alongside of the die 102 as shown.

Following electrical connection of the dies 102, 142 to the substrate 120, the DAF-C semiconductor device 140 may undergo an encapsulation process in step 236. As shown in the cross-sectional edge view of FIG. 13, a mold compound 146 may be applied over the components on the top surface 122 at the substrate 120 to encapsulate and protect the semiconductor dies 102, 142 and bond wires 144. Mold compound 146 may include for example solid epoxy resin, Phenol resin, fused silica, crystalline silica, carbon black and/or metal hydroxide. Other mold compounds from other manufacturers are contemplated. The mold compound may be applied by various known processes, including by FFT (flow free thin) molding, compression molding, transfer molding or injection molding techniques.

Referring again to FIG. 6, solder balls 148 may be affixed in step 238 to the contact pads 134 on the second major surface 124 of substrate 120 as shown for example in FIG. 13. The balls 148 may be solder, but may also be formed of copper, aluminum tin, gold, alloys thereof, or other flowable metals and materials in further embodiments. The solder balls 148 may be applied in a variety of different patterns in different embodiments.

At this stage in the assembly, the individual semiconductor devices 140 may still be part of a substrate panel. After the semiconductor devices 140 are encapsulated, they may be singulated from the panel in step 240 to form the completed DAF-C semiconductor device 140 as shown for example in the cross-sectional edge view of FIG. 13. The individual semiconductor devices 140 may be singulated from the panel using any of a variety of cutting methods including by saw blade, laser, waterjet or other methods. Once completed, the semiconductor devices 140 may be mounted to a printed circuit board (PCB) of a host device using solder balls 148.

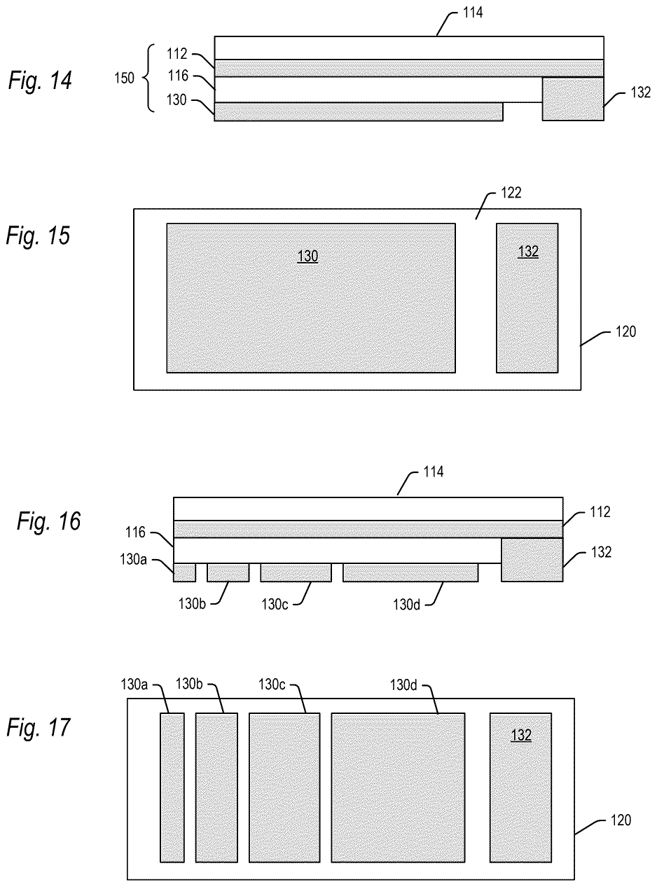

FIG. 14 is a cross-sectional view of the metal layer 112, DAF layer 114 and WEF layer 116 affixed to semiconductor die 102 (not shown) and the plate layer 130 and ground pad 132 of the substrate 120 (the rest of which is not shown). FIG. 15 is a top view of the substrate 120. In accordance with aspects of the present technology, once the die 102 and MEF 110 are assembled onto the substrate 120, the respective metal layers 112 and 130, separated by WEF 116, together form a capacitor, referred to herein as a DAF capacitor, or DAF-C, 150.

As shown and mentioned above, the ground pad 132, also referred to herein more generally as a built-up pad 132, extends above the surface of the substrate to embed within WEF 116 and into direct contact with metal layer 112. Thus, in embodiments, the metal layer 112 is connected to ground and acts as a reference plane of the DAF-C 150. The other metal layer, layer 130, may be connected to a variable voltage through the substrate 120, thus allowing the DAF-C 150 to act as a charge-storing capacitor for the semiconductor device 140. In further embodiments, instead of being a ground pad, the pad 132 (and by extension the metal layer 112) may be connected to a variable voltage source within the substrate 120, and the metal layer 130 may be connected to ground. In still further embodiments, the layer 112 and pad 132 may be connected to a first voltage and the layer 130 may be connected to a second, opposite voltage.

The thicknesses of layers 112 and 132 may vary in embodiments, but in one example, both may range from 5 μm to 20 μm, and more specifically about 10 μm. The layers 112 and 132 may be spaced from each other by the thickness of the WEF 116, which in embodiments may for example be 5 μm to 20 μm. The geometries of the metal layers, and their spacing from each other, may vary in further embodiments.

The DAF-C 150 is configured to store an electric charge (Q). The voltage (V) across the plates 112, 130 is related to the amount of charge stored:

Q=V·C (Eq. 1)
where C is the capacitance.
   The various parameters of DAF-C 150 may be configured to provide a wide variety of capacitive values, depending on its application. In one example, these values may range between 325 pF to about 1700 pF. The table 1 below shows example configurations of the DAF-C 150 and the produced capacitive value, where capacitive value, C, is given by:

C=(ε₀·k·A)/d, (Eq. 2)

and where:
ε₀=vacuum permittivity (electric constant)=8.854 pF/m;
k=relative permittivity (dielectric constant);
A=area of the metal plate layers; and
d=distance between the metal plate layers.

TABLE 1

| Metal plate Dimensions | | | WEF | | |
|---|---|---|---|---|---|
| | | Area A | Thickness | Dielectric | Capacitance |
| x (mm) | y (mm) | (mm²) | (d) (μm) | Constant (k) | C (pF) |
| 6.2 | 11.8 | 73.2 | 5 | 10 | 1296.2 |
| 6.2 | 11.8 | 73.2 | 7 | 10 | 926.0 |
| 6.2 | 11.8 | 73.2 | 10 | 10 | 648.1 |
| 6.2 | 11.8 | 73.2 | 15 | 10 | 432.1 |
| 6.2 | 11.8 | 73.2 | 20 | 10 | 324.1 |
| 12.4 | 7.9 | 98.0 | 5 | 10 | 1735.4 |
| 12.4 | 7.9 | 98.0 | 7 | 10 | 1239.6 |
| 12.4 | 7.9 | 98.0 | 10 | 10 | 867.7 |
| 12.4 | 7.9 | 98.0 | 15 | 10 | 578.5 |
| 12.4 | 7.9 | 98.0 | 20 | 10 | 433.8 |

In the embodiment shown in FIGS. 14 and 15, the metal layers 112, 120 are singular plates continuous along their length. Further customization of the DAF-C 150 may be provided by dividing one or both of the metal layers 112 and 130 into separate, discrete sections. An example of such an embodiment is shown in cross-sectional edge and top views of FIGS. 16 and 17. In the embodiment shown, the metal layer 130 in substrate 120 is divided into multiple sections 130a, 130b, 130c and 130d. The sections 130a-130d may be different sizes as shown, but they may be the same size in further embodiments. Where the metal layer 130 is divided into multiple sections, the metal layer 112 in MEF 110 may be a single continuous layer, but it may be divided into multiple sections like layer 130 in further embodiments. Moreover, in a still further embodiment, the metal layer 112 may be divided into multiple discrete sections of the same or differing sizes. In such a further embodiment, the metal layer 130 may be a single continuous layer, or multiple discrete sections.

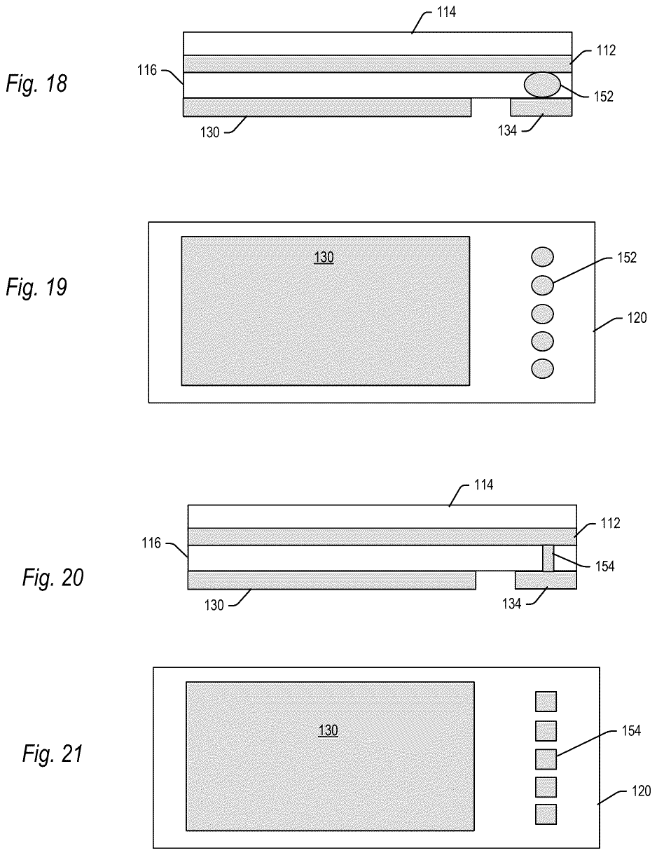

In the embodiments described above, the substrate incudes a pad 132 on substrate 120 that is built up so that it embeds the WEF 116 and into contact with metal layer 112 to electrically couple layer 112 to the substrate 120. In further embodiments, the metal layer 112 may be electrically coupled to the substrate 120 by other methods. For example, the cross-sectional edge and top views of FIGS. 18 and 19, the built-up pad 132 is omitted. In its place, contact pads 134 as described above are formed in the substrate in step 220 (FIG. 6). Thereafter, and before mounting the die 102 and MEF 110, a number of solder balls 152 may be mounted to the contact pads 134. When the die 102 and MEF 110 are then mounted to the substrate, the solder balls 152 embed within the WEF 116 and into contact with the metal layer 112 to electrically couple the metal layer 112 to the substrate 120.

The cross-sectional edge and top views of FIGS. 20 and 21 show another embodiment where the built-up pad 132 is omitted. In its place, contact pads 134 as described above are formed in the substrate. Thereafter, and before mounting the die 102 and MEF 110, a number of conductive columns 154 may be mounted to the contact pads 134. When the die 102 and MEF 110 are then mounted to the substrate, the metal columns 154 embed within the WEF 116 and into contact with the metal layer 112 to electrically couple the metal layer 112 to the substrate 120.

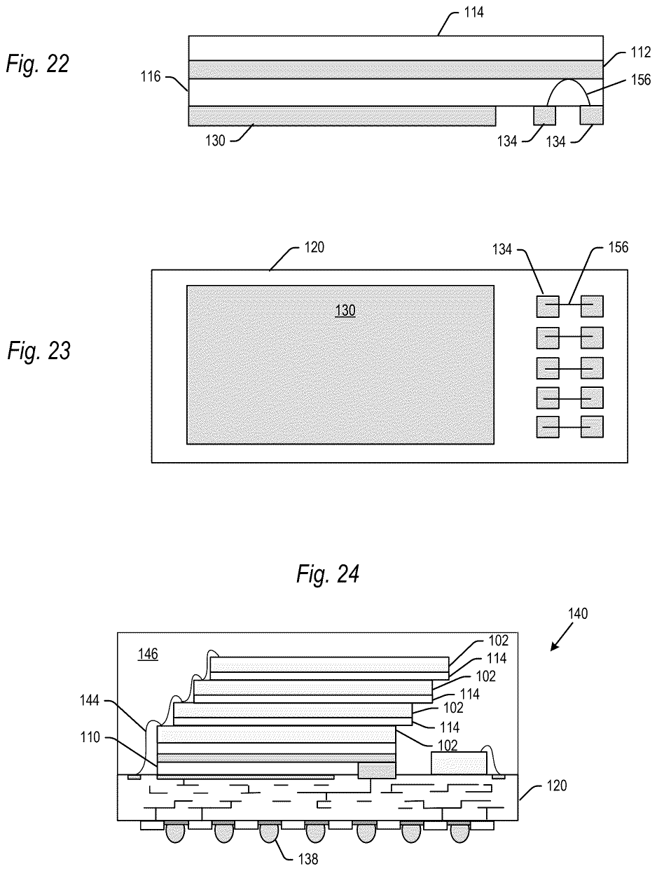

The cross-sectional edge and top views of FIGS. 22 and 23 show a further embodiment where the built-up pad 132 is omitted. In its place, two rows of contact pads 134 as described above are formed in the substrate. Thereafter, and before mounting the die 102 and MEF 110, bond wires 156 may be formed between each pair of contact pads 134, using for example a conventional wire bond capillary. When the die 102 and MEF 110 are then mounted to the substrate, the bond wires 156 embed within the WEF 116 and into contact with the metal layer 112 to electrically couple the metal layer 112 to the substrate 120.

The built-up pad 132, solder balls 152, metal columns 154 and bond wires 156 may generally be referred to herein as built-up electrical connectors. In addition to those described above, still further built-up electrical connectors are contemplated for electrically coupling the metal layer 112 to the substrate 120 upon mounting the die 102 and MEF 110 to the substrate.

In embodiments described above, a single memory die 102, including MEF 110, is mounted to the substrate 120. However, in further embodiments, it is understood that multiple memory dies 102 may be stacked on substrate 120. Such an embodiment is shown in the cross-sectional edge view of FIG. 24. In this embodiment, the bottommost die may include MEF 110 as described above, and may be affixed to the substrate 120 via WEF 116 as described above. Thereafter, one or more additional memory dies may be affixed on top of the bottommost semiconductor die 102. Such one or more additional memory dies may include a DAF layer 114 (but no metal layer 112 or WEF 116) to affix the dies to each other. As one example, the DAF 114 on each die 102 (and WEF on the bottommost die) may be cured to a B-stage to preliminarily affix the dies 102 in the stack, and subsequently cured to a final C-stage to permanently affix the dies 102 to the substrate 120. The number of dies 102 shown in the stack is by way of example only, and embodiments may include different numbers of semiconductor dies, including for example 1, 2, 4, 8, 16, 32 or 64 dies. There may be other numbers of dies in further embodiments. In further embodiments, the dies may be electrically connected by other methods, including for example through silicon vias (TSVs). In such embodiments, the TSVs would be formed through the dies and into contact with portions of the substrate away from the metal layer 130 and built-up pad 132.

In summary, examples of the present technology relate to a semiconductor device, comprising: a substrate; a semiconductor die mounted to the substrate; and a capacitor configured to store an electric charge, the capacitor integrated into the semiconductor device.

In another example, the present technology relates to a semiconductor device, comprising: a substrate comprising: a first metal plate, and a built-up electrical connector; a semiconductor die; and a metal embedded film (MEF) affixed to a surface of the semiconductor die, the MEF comprising: a die attach film (DAF) affixed to a surface of the semiconductor die, a second metal plate affixed to a surface of the DAF, a wire embedded film (WEF) affixed to a surface of the metal layer; wherein the semiconductor die and MEF are affixed to the substrate, with the built-up electrical connector electrically coupling to the first metal plate, and wherein the first and second plates together form a capacitor for storing an electric charge.

In a further example, the present technology relates to a semiconductor device, comprising: a substrate; a semiconductor die; a film configured to affix the semiconductor die and the substrate; and capacitor means in or on the substrate and film for storing an electric charge.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed is:

1. A semiconductor device, comprising:
a substrate;
a semiconductor die mounted to the substrate; and
a capacitor configured to store an electric charge, the capacitor integrated into the semiconductor device.

2. The semiconductor device of claim 1, further comprising a film between the semiconductor die and the substrate, the film configured to affix the semiconductor die to the substrate, and wherein the film comprises a first plate of the capacitor.

3. The semiconductor device of claim 2, wherein the substrate comprises a surface, and a second plate of the capacitor provided on the surface, the first and second plates spaced from and overlapping each other in the semiconductor device.

4. The semiconductor device of claim 3, wherein the first and second plates each comprise singular plates continuous along their length.

5. The semiconductor device of claim 3, wherein at least one of the first and second metal plates are divided into separate, discrete sections.

6. The semiconductor device of claim 2, wherein the film further comprises:
a die attach film (DAF) comprising a first surface affixed to a surface of the semiconductor die, and a second surface affixed to the first plate of the capacitor; and
a wire embedded film (WEF) comprising a first surface affixed to a surface of the substrate, and a second surface affixed to the first plate, so that the plate is sandwiched between the DAF and WEF.

7. The semiconductor device of claim 6, further comprising a built-up electrical connector electrically coupling the first plate to the substrate.

8. The semiconductor device of claim 7, wherein the built-up electrical connector comprises a first end in direct contact with the substrate and a second end in direct contact with the first plate.

9. The semiconductor device of claim 7, wherein the built-up electrical connector is embedded in the WEF.

10. The semiconductor device of claim 7, wherein the built-up electrical connector comprises built-up metal layers extending out of a plane of the surface of the substrate.

11. A semiconductor device, comprising:
a substrate comprising:
a first metal plate, and
a built-up electrical connector;
a semiconductor die; and
a metal embedded film (MEF) affixed to a surface of the semiconductor die, the MEF comprising:
a die attach film (DAF) affixed to a surface of the semiconductor die,
a second metal plate affixed to a surface of the DAF,
a wire embedded film (WEF) affixed to a surface of the metal layer;
wherein the semiconductor die and MEF are affixed to the substrate, with the built-up electrical connector electrically coupling to the first metal plate, and
wherein the first and second plates together form a capacitor for storing an electric charge.

12. The semiconductor device of claim 11, wherein the first and second plates each comprise singular plates continuous along their length.

13. The semiconductor device of claim 11, wherein at least one of the first and second metal plates are divided into separate, discrete sections.

14. The semiconductor device of claim 11, wherein the built-up electrical connector is embedded in the WEF.

15. The semiconductor device of claim 11, wherein the built-up electrical connector comprises a first end in direct contact with the substrate and a second end in direct contact with the first plate.

16. The semiconductor device of claim 11, wherein the built-up electrical connector comprises built-up metal layers extending out of a plane of the surface of the substrate.

17. The semiconductor device of claim 11, wherein the built-up electrical connector comprises one of solder balls, metal columns and bond wires.

18. The semiconductor device of claim 11, wherein the semiconductor die comprises a first memory die, the semiconductor device further comprising a group of one more additional memory dies stacked on the first memory die.

19. The semiconductor device of claim 11, wherein the capacitor has a capacitance ranging between 325 pF to about 1700 pF.

20. A semiconductor device, comprising:
a substrate;
a semiconductor die;
a film configured to affix the semiconductor die and the substrate; and
capacitor means in or on the substrate and film for storing an electric charge.
